(19) United States
(12) Patent Application Publication
(10) Pub. No.: US 2018/0124929 A1
(43) Pub. Date: May 3, 2018

(54) ELECTRONIC DEVICE

(71) Applicant: FUJITSU LIMITED, Kawasaki-shi (JP)

(72) Inventor: HIROMU SHOJI, Kawasaki (JP)

(73) Assignee: FUJITSU LIMITED, Kawasaki-shi (JP)

(21) Appl. No.: 15/729,254

(22) Filed: Oct. 10, 2017

(30) Foreign Application Priority Data
Oct. 28, 2016 (JP) 2016-212048

(51) Int. Cl. H05K 5/00; H05K 5/02

(52) U.S. Cl. CPC H05K 5/0004; H05K 5/0217

(57) ABSTRACT

An electronic device includes a first case, a second case that is fastened to the first case in a first direction and has an outer circumferential part with a groove formed recessed in a second direction different from the first direction, and an elastic member that has a ring shape and fits into the groove to be retained in an elastically deformed state between the first case and the second case.

### CROSS-REFERENCE TO RELATED APPLICATION

This application is based upon and claims the benefit of priority of the prior Japanese Patent Application No. 2016-212048, filed on Oct. 28, 2016, the entire contents of which are incorporated herein by reference.

### FIELD

The embodiment discussed herein is related to an electronic device.

### BACKGROUND

A technique is known that uses an elastic member such as a gasket to enhance sealability (waterproof performance) between two cases that are fastened to each other.

However, with a conventional technique as described above, it is difficult to promote miniaturization of an electronic device including two cases that are fastened to each other. A structure in which an elastic member is retained in an elastically deformed state to secure sealability may be a factor that causes a raised part or the like at the side of a case member. This easily hinders reducing the outer dimension of the electronic device.

The followings are reference documents.
[Document 1] Japanese Laid-open Patent Publication No. 2012-114177,
[Document 2] Japanese Laid-open Patent Publication No. 11-346064, and
[Document 3] Japanese Laid-open Patent Publication No. 11-150384.

### SUMMARY

According to an aspect of the invention, an electronic device includes a first case, a second case that is fastened to the first case in a first direction and has an outer circumferential part with a groove formed recessed in a second direction different from the first direction, and an elastic member that has a ring shape and fits into the groove to be retained in an elastically deformed state between the first case and the second case.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view of an electronic device according to an embodiment;

FIG. 2 is a top view of the electronic device;

FIG. 3 is a cross-sectional view taken along the line III-III in FIG. 2;

FIG. 4 is an enlarged view of a part IV in FIG. 3;

FIG. 5 is a plan view illustrating a lower case viewed from the top in a state in which a rubber gasket is attached; and

FIG. 6 is a diagram illustrating a comparison example.

### DESCRIPTION OF EMBODIMENT

Hereinafter, with reference to the drawings, an embodiment will be described in details.

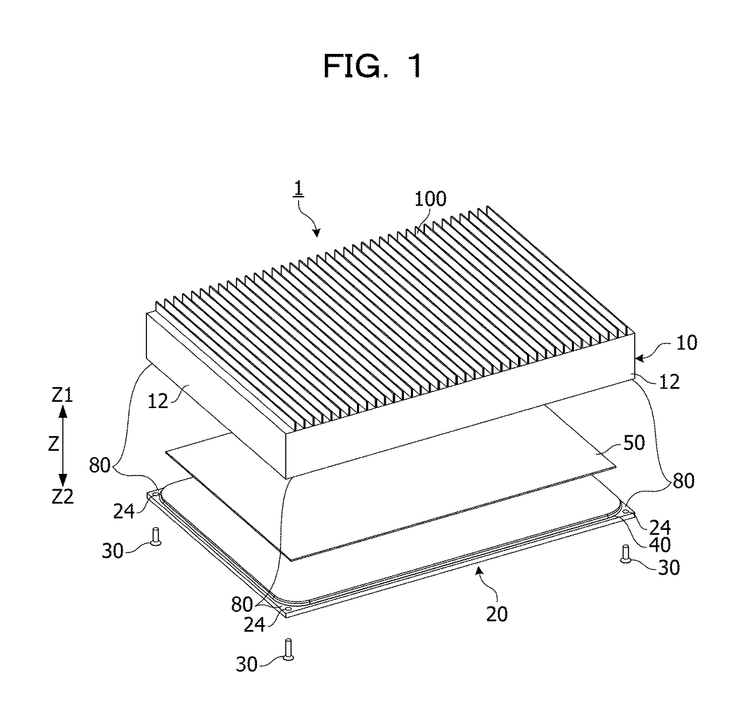

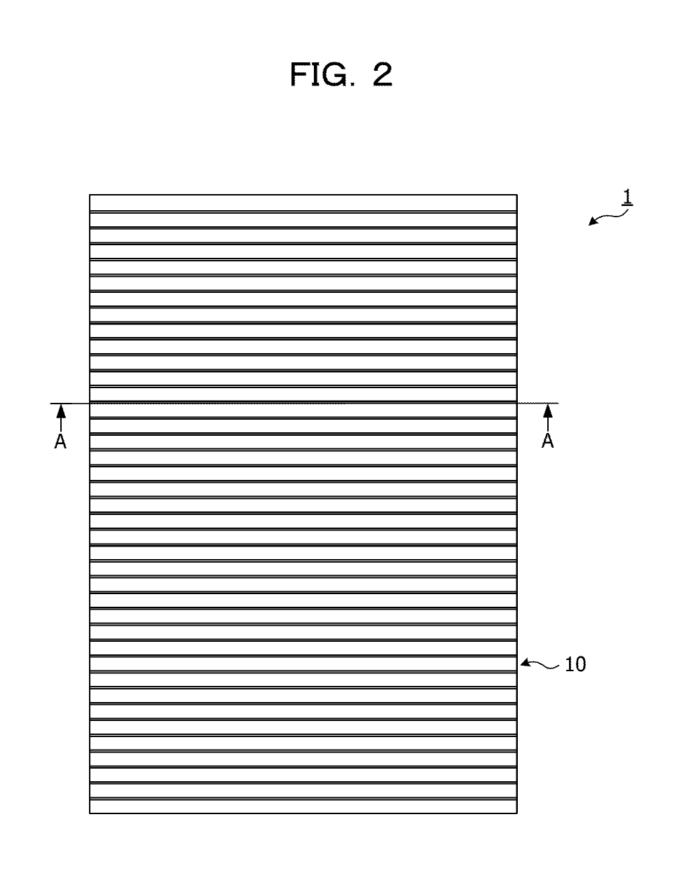

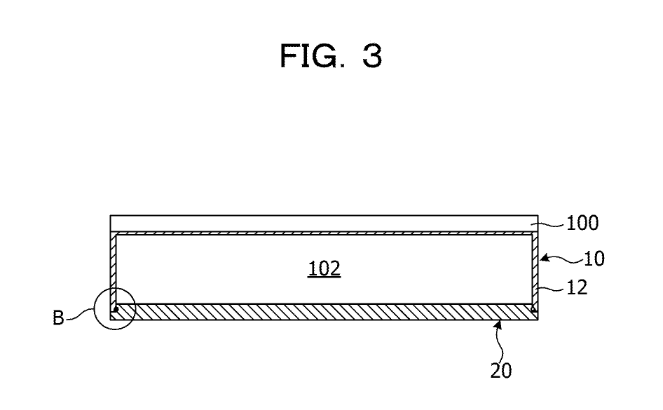

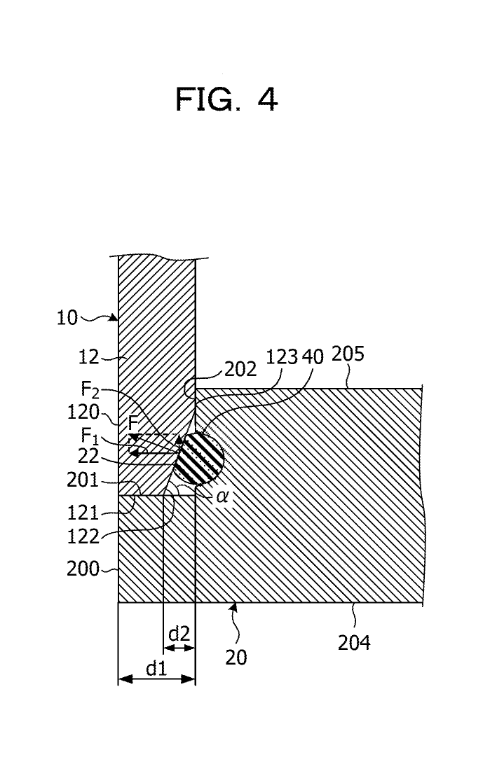

FIG. 1 is an exploded perspective view of an electronic device 1 according to an embodiment. FIG. 2 is a top view of the electronic device 1. FIG. 3 is a cross-sectional view taken along the line III-III in FIG. 2. In FIG. 3, illustration of components within an internal space 102 is omitted. FIG. 4 is an enlarged view of a part IV in FIG. 3.

The electronic device 1 is waterproof as described later and thus suitably placed outdoors. The electronic device 1 is an outdoor base station device, for example. In the description below, the electronic device 1 is to be an outdoor base station device, as an example.

In FIG. 1, a Z direction corresponding to the height direction of the electronic device 1 is illustrated. In the description below, for the sake of explanation, the Z1 side of the Z direction is to be the “upper side”, and the Z2 side is to be the “lower side”. However, the up and down direction of the electronic device 1 at the time of installation is optional. Furthermore, in the description below, the “outer side” indicates the side closer to the outside of the electronic device 1, and the “inner side” indicates the side closer to the inner center of the electronic device 1. Furthermore, in the description below, the direction perpendicular to the Z direction is also referred to as the “horizontal direction”, and a “side face” indicates a face that faces the horizontal direction.

As illustrated in FIG. 1, the electronic device 1 includes an upper case 10 (an example of a first case), a lower case 20 (an example of a second case), screws 30, a rubber gasket 40 (an example of an elastic member), and a substrate 50.

The upper case 10 opens at the lower side thereof in the Z direction. The upper case 10 has a substantially rectangular outer shape as viewed from the top (view of the Z2 side from the Z1 side in the Z direction, hereinafter indicates the same). The “substantially rectangular shape” indicates that R finishing or chamfering may be applied at the four corners of the rectangle. The upper case 10 forms the internal space 102 (see FIG. 3) whose cross section is substantially rectangular and contains the substrate 50, an electronic part on the substrate 50 (not illustrated), and the like using the internal space 102.

The upper case 10 has side walls 12. The side walls 12 form side faces on the periphery of the upper case 10. That is to say, the side walls 12 surround the internal space 102 from the outside over the entire periphery to define the internal space 102.

The side faces of the periphery of the upper case 10 is desirably parallel with the Z direction and have no unevenness, as illustrated in FIGS. 1 and 4. This enables to suppress the outer dimension of the electronic device 1 from increasing due to unevenness or the like of the side faces of the upper case 10.

The upper case 10 has fins 100 on the surface of the upper side (outer surface at the opposite side of the opening side), as illustrated in FIG. 1. The fins 100 are exposed to the outdoor air. The fins 100 have a function of increasing the surface area of the upper case 10 to effectively release heats of electronic parts mounted on the substrate 50 to the outside. It is to be noted that the cooling method of the electronic device 1 may be other methods such as water cooling.

The lower case 20 covers the opening of the upper case 10. That is to say, the lower case 20 covers the Z2 side of the upper case 10 and functions as a lower lid of the upper case 10. The lower case 20 has a substantially rectangular outer shape corresponding to the outer shape of the upper case 10.

The lower case 20 has a groove 22 on the outer circumferential part thereof, as illustrated in FIGS. 3 and 4. The groove 22 is formed over the entire periphery of the outer circumferential part of the lower case 20. The groove 22 is formed recessed in the horizontal direction over the entire periphery of the outer circumferential part of the lower case 20. That is to say, the groove 22 is recessed to the inside over the entire periphery of the outer circumferential part of the lower case 20. The shape of the groove 22 in a cross-sectional view may be semicircular corresponding to the cross-sectional shape of the rubber gasket 40 which is circular, as illustrated in FIG. 4. However, the shape of the groove 22 in a cross-sectional view may be a shape other than a semicircular shape, for example, a rectangular shape. Furthermore, the shape of the groove 22 in a cross-sectional view may be a semicircular shape slightly larger than the cross-sectional shape of the rubber gasket 40 which is circular to secure a crush margin of the rubber gasket 40.

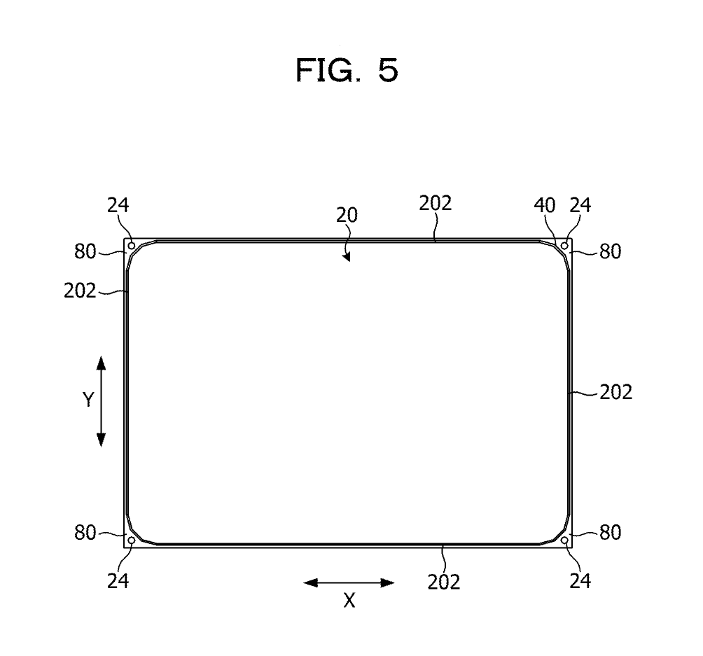

The lower case 20 has holes 24 at the four corners thereof through which the screws 30 pass, as illustrated in FIGS. 1 and 5. FIG. 5 is a plan view illustrating the lower case 20 viewed from the top in a state in which the rubber gasket 40 is attached. Each of the holes 24 of the lower case 20 may have an outer diameter slightly larger than that of the shaft part of each of the screws 30.

The screws 30 fasten the lower case 20 to the upper case 10. The screws 30 generate fastening forces in the Z direction between the upper case 10 and the lower case 20. That is to say, the fastening direction of the screws 30 is the Z direction. As illustrated in three points in FIG. 1, four screws 30 are provided corresponding to four points of fastening parts 80. It is to be noted that instead of the screws 30, fastening tools in other forms such as bolts may be used.

At four points of the fastening parts 80, the holes 24 of the lower case 20 and screw holes (not illustrated) at the side of the upper case 10 are arranged. Each of the screws 30 passes through the corresponding hole 24 to be screwed with the corresponding screw hole. That is to say, the screws 30 are screwed to the upper case 10 via the lower case 20, thereby fastening the lower case 20 to the upper case 10.

The rubber gasket 40 is formed of an elastic material (rubber). The rubber gasket 40 has a cross section that fits in the groove 22 of the lower case 20 and has a ring shape as viewed from the top, as illustrated in FIGS. 1 and 5. The rubber gasket 40 is retained in an elastically deformed state between the upper case 10 and the lower case 20 so as to increase sealability (waterproof performance) against liquid (for example, water) that may enter between the upper case 10 and the lower case 20. A retention mode of the rubber gasket 40 (a retention mode of the rubber gasket 40 between the upper case 10 and the lower case 20) will be described later in details.

The rubber gasket 40 is attached into the groove 22 of the lower case 20 desirably in the mode in which no loosening is generated. This enables good fitting of the rubber gasket 40 (that is, biting of the rubber gasket 40) into the groove 22, thereby enhancing attachability of the rubber gasket 40 into the groove 22 of the lower case 20. Furthermore, this enables to reduce a possibility that the rubber gasket 40 comes out of the groove 22 at the time of assembly between the upper case 10 and the lower case 20, for example. For example, the rubber gasket 40 may be attached into the groove 22 of the lower case 20 in a mode in which some tension is generated.

On the substrate 50, various electronic parts of the electronic device 1 are mounted. The various electronic parts may be a transmitting and receiving device, a power amplifier (PA), a low noise amplifier (LNA), a filter, and the like, for example. Specific electronic parts on the substrate 50 are thermally connected to the upper case 10 and heats from the electronic parts are transmitted to the upper case 10, for example.

Next, with reference to FIG. 4, for example, the upper case 10 and the lower case 20 will be described in more details.

The outer circumferential part of the lower case 20 includes outermost side faces 200 and an inner side face 202 (an example of a second surface), as illustrated in FIG. 4. The outer circumferential part of the lower case 20 further includes supporting faces 201 extending from the outermost side faces 200 to the inner side face 202, as illustrated in FIG. 4.

The outermost side faces 200 extend from an undersurface 204 of the lower case 20 to the upper side in the Z direction. The outermost side faces 200 are side faces that decide the outer dimension of the electronic device 1, for example.

The supporting faces 201 form surfaces (an example of first surfaces) whose normal direction is the Z direction. The supporting faces 201 abut end faces 121 on the lower side of side walls 12 of the upper case 10 in the Z direction. With this, the supporting faces 201 have a supporting function that supports the lower edges of the side walls 12 in the Z direction. To enhance this supporting function, a width d1 of the supporting faces 201 is desirably equal to or larger than the board thickness of the side walls 12 of the upper case 10. In the example illustrated in FIG. 4, the width d1 of the supporting faces 201 corresponds to the board thickness of the side walls 12 of the upper case 10. Furthermore, to enhance the supporting function, the supporting faces 201 are flat over the entire surface thereof.

On the inner side face 202, the groove 22 described above is formed. The inner side face 202 is offset to the side inner than the outermost side faces 200. The inner side face 202 faces the lower edge of the side walls 12 of the upper case 10 from the inner side. The inner side face 202 is perpendicular to the supporting faces 201. However, the inner side face 202 may have a slight inclination with respect to the supporting faces 201.

The inner side face 202 desirably extends in an arc shape at each of the four corners thereof as viewed from the top, as illustrated in FIG. 5. That is to say, the inner side face 202 whose normal vector is along the X direction in FIG. 5 and the inner side face 202 whose normal vector is along the Y direction in FIG. 5 continue from each other via a curved face. With this, as illustrated in FIG. 5, a space for forming the fastening parts 80 (space for providing the holes 24 or the like) of the lower case 20 is able to be secured at the four corners to enhance miniaturization of the electronic device 1.

Each of the side walls 12 of the upper case 10 includes an outermost side face 120, an end face 121, an inclined face 122, and an inner surface 123 at the lower edge thereof.

The outermost side faces 120 are formed on the same planes with the outermost side faces 200 of the lower case 20, for example, and are side faces that decide the outer dimension of the electronic device 1. The outermost side faces 120 form the side faces of the lower case 20.

The end faces 121 abut the supporting faces 201 of the lower case 20 in the Z direction, as described above. It is to be noted that on the end faces 121, at the four corners of the upper case 10, screw holes (not illustrated) for screws 30 are formed in the Z direction.

The inclined faces 122 are formed between the end faces 121 and the inner surfaces 123. The inclined faces 122 may be formed as chamfering parts at the corners between the end faces 121 and the inner surfaces 123. The inclined faces 122 incline towards the directions in which the lower edge sides are away from the groove 22. Organizing the inclined faces 122 enables to reduce a possibility that an end face 121 of a side wall 12 of the upper case 10 abuts the rubber gasket 40 in the Z direction at the time of assembly of the upper case 10 to the lower case 20 onto which the rubber gasket 40 is attached. To enhance such a function of the inclined faces 122 (function of suppressing entrapment of the rubber gasket 40), a chamfering width d2 related to the inclined faces 122 may be set slightly larger than the amount of protrusion of the rubber gasket 40 from the inner side face 202.

The inner surfaces 123 face the inner side face 202 of the lower case 20. The inner surfaces 123 may contact (abut) the inner side face 202 of the lower case 20, and a small clearance between the inner surfaces 123 and the inner side face 202 may be set.

Next, still with reference to FIG. 4, the retention mode of the rubber gasket 40 will be described.

The rubber gasket 40 is provided between the outer circumferential part of the lower case 20 and the side walls 12 of the upper case 10. The rubber gasket 40 is retained in an elastically deformed state, as illustrated with a schematic noncircular cross section (before elastically deformed, circular cross section) in FIG. 4. When the rubber gasket 40 is in a state fitted into the groove 22 and pressed from the inclined faces 122 of the upper case 10, the rubber gasket 40 is elastically deformed. With this, when the rubber gasket 40 fills a space between the inclined faces 122 of the upper case 10 and the inner side face 202 of the lower case 20, the rubber gasket 40 is elastically deformed. This enables to achieve a sealing function between the upper case 10 and the lower case 20.

The rubber gasket 40 is attached into the groove 22 which is formed recessed in the horizontal direction, and thus generates an elastic force F (see FIG. 4) that has a horizontal component F₁ when the rubber gasket 40 is in an elastically deformed state. In the present embodiment, because the rubber gasket 40 is pressed by the inclined faces 122, the direction of the elastic force F substantially corresponds to the direction perpendicular to the inclined faces 122. In this case, the elastic force F thus has a Z-direction component F₂ as well as the horizontal component F₁.

At this point, the elastic deformation amount of the rubber gasket 40 is decided by the cross-sectional shape of the rubber gasket 40, a space between the groove 22 and the inclined faces 122, or the like. The elastic deformation amount of the rubber gasket 40 is a parameter that determines the magnitude of the elastic force F (see FIG. 4), along with the elastic ratio of the rubber gasket 40 and the like. The elastic deformation amount of the rubber gasket 40 is decided so as to generate the elastic force F having a magnitude that enables to secure adequate sealability.

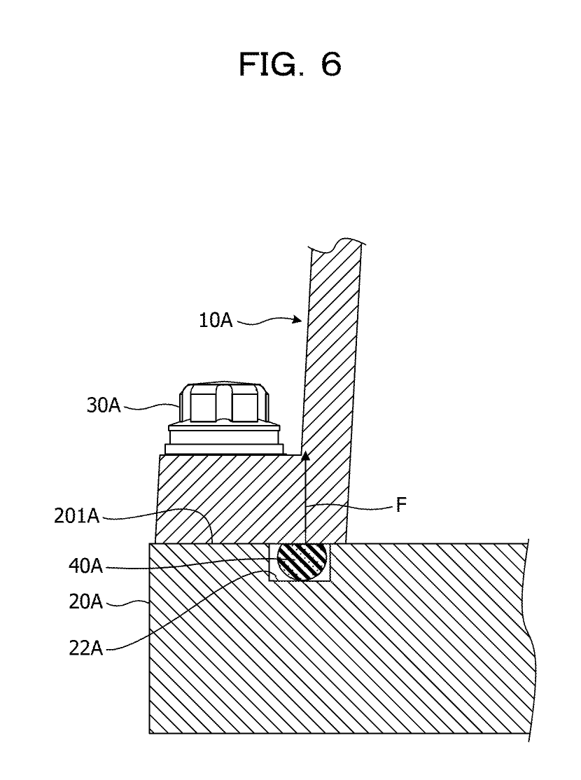

Next, with reference to a comparison example in FIG. 6, an effect of the present embodiment will be described.

FIG. 6 illustrates a cross-sectional view of the comparison example as a contrast to the cross sectional view according to the present embodiment which is illustrated in FIG. 4. In the comparison example in FIG. 6, on a supporting face 201A of a lower case 20A, a groove 22A recessed in the Z direction is formed. Into the groove 22A, a rubber gasket 40A is set. Between an upper case 10A and the lower case 20A, the rubber gasket 40A is retained in an elastically deformed state, whereby sealability is secured between the upper case 10A and the lower case 20A which are fastened to each other with a screw 30A.

The rubber gasket 40 (similarly to the rubber gasket 40A in the comparison example) is retained in an elastically deformed state to secure sealability, as described above. To perform the retention in such an elastically deformed state, the fastening force of the screws 30 (similarly to the screws 30A in the comparison example) has a magnitude with which the engagement between the upper case 10 and the lower case 20 is not damaged, stemming from the elastic force of the rubber gasket 40 in an elastically deformed state. The fastening force of the screws 30 is generated in the Z direction. Accordingly, the adequate magnitude of the fastening force of the screws 30 is decided depending on the Z-direction component of the elastic force of the rubber gasket 40.

In this respect, the direction of the elastic force F is parallel with the Z direction in the comparison example in FIG. 6. Accordingly, the adequate magnitude of the fastening force of the screws 30A is decided depending on the magnitude of the elastic force F itself which is the Z-direction component of the elastic force F.

By contrast, in the present embodiment, as described above, the rubber gasket 40 is attached into the groove 22 which is formed recessed in the horizontal direction, whereby the direction of the elastic force F stemming from the elastic deformation of the rubber gasket 40 is not parallel with the Z direction (that is, different from the Z direction). Specifically, the direction of the elastic force F substantially corresponds to the direction perpendicular to the inclined faces 122. Accordingly, in the present embodiment, as described above, the Z-direction component F₂ of the elastic force F is smaller than that in the comparison example in FIG. 6. In this manner, in the present embodiment, the adequate magnitude of the elastic force F is able to be secured while reducing the magnitude of the Z-direction component F₂ of the elastic force F. With this, the adequate magnitude of the fastening force of the screws 30 is able to be reduced to miniaturize the fastening parts 80. It is to be noted that the miniaturization of the fastening parts 80 is able to be enhanced by reducing the number of pieces of the screws 30 (the number of the fastening parts 80), miniaturizing the screws 30 themselves, reducing the rigidity of the fastening parts 80, or the like, for example. Consequently, the present embodiment enables miniaturization of the electronic device 1.

Specifically, in the present embodiment, as described above, the number of pieces of the screws 30 may be set to four, for example, to set the fastening parts of the screws 30 only at the four corners on the electronic device 1. With this, as illustrated in FIG. 5, the fastening parts of the screws 30 are able to be arranged at the sides outer than the rubber gasket 40 and inner than the outermost side faces 120 of the side walls 12 in the upper case 10 of the electronic device 1. In this manner, the present embodiment enables miniaturization of the electronic device 1, compared with a comparison example (not illustrated) in which a raised part or the like is provided on outermost side faces of a case unit to secure fastening parts of screws.

To secure the adequate magnitude of the elastic force F while reducing the magnitude of the Z-direction component F₂ of the elastic force F, it is desirable that the retention mode of the rubber gasket 40 allow the elastic force F to be generated whose horizontal component F₁ is significantly larger than the Z-direction component F₂. The ratio of the horizontal component F₁ to the Z-direction component F₂ of the elastic force F is roughly decided by the degree of inclination of the inclined faces 122. For example, to generate the elastic force F whose horizontal component F₁ is significantly larger than the Z-direction component F₂, an angle a (see FIG. 4) of the inclined faces 122 with respect to the horizontal direction is set to be significantly larger than 45 degrees. That is to say, the angle a is desirably set to an angle ranging from 45 degrees to less than 90 degrees, and is more desirably less than 90 degrees and significantly larger than 45 degrees.

Furthermore, according to the present embodiment, the rubber gasket 40 is arranged at the sides inner than the fastening parts 80 between the upper case 10 and the lower case 20 and abutting areas (abutting areas between the end faces 121 and the supporting faces 201). With this, compared with the comparison example in FIG. 6 in which the rubber gasket 40A is provided in abutting areas, the present embodiment enables to enhance waterproof performance.

Although an embodiment has been described above, the present disclosure is not limited to a specific embodiment, and various modifications and changes may be made within the scope described in the claims. Furthermore, all or a plurality of components in the embodiment described above may be combined.

For example, in the embodiment described above, the electronic parts in the electronic device 1 are thermally connected to the upper case 10 and the fins 100 are provided on the upper case 10. However, the present disclosure is not limited to this. The electronic parts in the electronic device 1 may be thermally connected to the lower case 20, and the fins may be provided on the lower case 20.

Furthermore, in the embodiment described above, the inclined faces 122 are provided. However, the inclined faces 122 may be omitted. That is to say, the inclined faces 122 may be substituted by uninclined faces whose angle a (see FIG. 4) is 90 degrees. In this case, the magnitude of the Z-direction component F₂ of the elastic force F of the rubber gasket 40 is approximately 0 (that is, substantially only the horizontal component F₁ is present). It is to be noted that in this case, the groove 22 is formed in a shape that is able to contain crush margin of the rubber gasket 40.

Furthermore, in the embodiment described above, the lower case 20 does not form the internal space 102 in the electronic device 1. However, the present disclosure is not limited to this. For example, a cavity recessed in the Z direction may be formed on an upper face 205 so that the cavity forms an internal space in the electronic device 1. In this case, the height of the cavity of the lower case 20 may be increased (that is, side walls are formed) and the height of the upper case 10 is reduced (that is, the side walls 12 are not present) to reverse the roles of the upper case 10 and the lower case 20.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic device comprising:
a first case;
a second case that is fastened to the first case in a first direction and has an outer circumferential part with a groove formed recessed in a second direction different from the first direction; and
an elastic member that has a ring shape and fits into the groove to be retained in an elastically deformed state between the first case and the second case.

2. The electronic device according to claim 1,
wherein the second direction is perpendicular to the first direction.

3. The electronic device according to claim 1,
wherein the first case has an opening towards the first direction,
the second case covers the opening of the first case,
the outer circumferential part of the second case has a first surface with a normal direction being the first direction and a second surface with the groove formed at a side inner than the first surface and with a normal direction being the second direction, and
the first case abuts the first surface in the first direction.

4. The electronic device according to claim 3,
wherein the first case has a side wall that abuts the first surface in the first direction and faces the second surface in the second direction, and
the elastic member is retained between the side wall of the first case and the second surface of the second case.

5. The electronic device according to claim 4,
wherein the side wall has an inclined face that presses the elastic member at an edge at a side of abutting the first surface in the first direction.

6. The electronic device according to claim 5,
wherein the inclined face forms a surface that forms an angle between 0 to 45 degrees with respect to the first direction.

7. The electronic device according to claim 4,
wherein a side face of a periphery of the first case is parallel with the first direction and has no unevenness.

8. The electronic device according to claim 3,
wherein the first case and the second case have outer shapes, the outer shapes being rectangular shapes, as viewed in the first direction, and
the first case and the second case are fastened to each other at four corners of the rectangular shapes.

9. The electronic device according to claim 8,
wherein the second surface extends in an arc shape at the four corners as viewed in the first direction.

10. The electronic device according to claim 1,
wherein one of the first case and the second case has a fin on an outer surface.

11. The electronic device according to claim 1,
wherein the electronic device is a base station device that is placed outdoors.

12. The electronic device according to claim 1,
wherein the elastic member is made of rubber.

13. The electronic device according to claim 1,
wherein the elastic member generates some tension.

14. The electronic device according to claim 1,
wherein the elastic member is disposed at a side inner than a fastening part between the first case and the second case.

15. The electronic device according to claim 1,
wherein the elastic member generates an elastic force that has a component in the second direction.
